(19) United States
(12) Patent Application Publication
(10) Pub. No.: US 2026/0269800 A1
(43) Pub. Date: Sep. 10, 2026

(54) ELECTRONIC COMPONENT

(71) Applicant: TDK Corporation, Tokyo (JP)

(72) Inventors: Yu FUKAE, Tokyo (JP); Atsuhiro TSUYOSHI, Tokyo (JP); Takashi OHTSUKA, Tokyo (JP); Yoshinori UCHIYAMA, Tokyo (JP); Takeshi OOHASHI, Tokyo (JP); Yusuke TAKIGUCHI, Tokyo (JP)

(73) Assignee: TDK Corporation, Tokyo (JP)

(21) Appl. No.: 19/557,881

(22) Filed: Mar. 5, 2026

(30) Foreign Application Priority Data
Mar. 7, 2025 (JP) 2025-036591

(51) Int. Cl. H03H 7/01; H03H 1/00

(52) U.S. Cl. CPC H03H 7/0161; H03H 1/00; H03H 2001/0085

(57) ABSTRACT

An electronic component includes: a substrate; and an element body disposed on the substrate and including a pair of main surfaces facing each other and four side surfaces connecting the pair of main surfaces, in which the element body includes a plurality of conductor layers and insulating layers, the plurality of conductor layers include a first conductor layer disposed on the substrate and a second conductor layer disposed on the first conductor layer, the first conductor layer includes a first conductor pattern, the second conductor layer includes a second conductor pattern, the first conductor pattern is covered with an adhesion layer, and there is a region in which a distance from one side surface to the adhesion layer is equal to or less than a thickness of the second conductor pattern.

### TECHNICAL FIELD

The present disclosure relates to an electronic component.

### BACKGROUND

Japanese Unexamined Patent Publication No. 2021-101480 discloses an electronic component including: a substrate; a lower electrode formed on the substrate; a dielectric film formed on the lower electrode; an upper electrode formed of a metal or a conductor containing a metal on a part of the dielectric film; a protective layer covering the lower electrode and the upper electrode and formed of a resin material; a first external electrode penetrating the protective layer and coupled to the upper electrode; and a second external electrode penetrating the protective layer and the dielectric film and coupled to the lower electrode, in which the first external electrode is formed only in a region defined by a peripheral edge of the upper electrode in a plan view of a capacitor viewed from above, and the second external electrode is disposed in contact with the dielectric film.

### SUMMARY

An electronic component according to an aspect of the present disclosure includes: a substrate; and an element body disposed on the substrate and including a pair of main surfaces facing each other and four side surfaces connecting the pair of main surfaces, in which the element body includes a plurality of conductor layers and insulating layers, the plurality of conductor layers include a first conductor layer disposed on the substrate and a second conductor layer disposed on the first conductor layer, the first conductor layer includes a first conductor pattern, the second conductor layer includes a second conductor pattern, the first conductor pattern is covered with an adhesion layer, and there is a region in which a distance from one side surface to the adhesion layer is equal to or less than a thickness of the second conductor pattern.

### BRIEF DESCRIPTION OF THE DRAWINGS

FIG. 1 is a perspective view of an electronic component according to an embodiment;

FIGS. 2A, 2B, and 2C are views illustrating layers constituting an element body;

FIGS. 3A, 3B, and 3C are views illustrating layers constituting the element body;

FIGS. 4A, 4B, and 4C are views illustrating layers constituting the element body;

FIGS. 5A and 5B are views illustrating layers constituting the element body;

FIG. 6 is an enlarged cross-sectional view illustrating a part of the electronic component; and

FIG. 7 is a cross-sectional view of a stacked body before the electronic component is divided into individual pieces.

### DETAILED DESCRIPTION

### Problems to be Solved by the Present Disclosure

An electronic component manufacturing process includes a cutting step of cutting a stacked body into individual pieces. In the cutting step, the stacked body is cut by a cutting blade (dicing blade). When the stacked body is cut, if a distance between a cut surface (a surface to be a side surface of an element body of an electronic component) and a conductor pattern is short, the conductor pattern disposed on a substrate may be peeled off from the substrate. Therefore, it is necessary to ensure the distance between the cut surface and the conductor pattern. However, when the distance between the cut surface and the conductor pattern is ensured, an area (design area) in which the conductor pattern is disposed cannot be ensured. In order to improve characteristics of the electronic component, it is required to ensure an area in which the conductor pattern is disposed.

An object of an aspect of the present disclosure is to provide an electronic component capable of ensuring an area in which a conductor pattern is disposed when the electronic component is manufactured while a manufacturing process thereof includes a cutting step.

### Effects of Present Disclosure

According to an aspect of the present disclosure, it is possible to ensure an area in which a conductor pattern is disposed when an electronic component is manufactured while a manufacturing process thereof includes a cutting step.

### Description of Embodiments of Present Disclosure

First, contents of embodiments of the present disclosure will be listed and described. At least some of the embodiments described below may be arbitrarily combined with each other.
(1) An electronic component according to an aspect of the present disclosure includes: a substrate; and an element body disposed on the substrate and including a pair of main surfaces facing each other and four side surfaces connecting the pair of main surfaces, in which the element body includes a plurality of conductor layers and insulating layers, the plurality of conductor layers include a first conductor layer disposed on the substrate and a second conductor layer disposed on the first conductor layer, the first conductor layer includes a first conductor pattern, the second conductor layer includes a second conductor pattern, the first conductor pattern is covered with an adhesion layer, and there is a region in which a distance from one side surface to the adhesion layer is equal to or less than a thickness of the second conductor pattern.

In the electronic component according to the aspect of the present disclosure, the first conductor pattern is covered with the adhesion layer. This makes it possible to suppress peeling of the first conductor pattern when cutting is performed in a manufacturing process. Therefore, the electronic component has a region in which a distance from one side surface to the adhesion layer is equal to or less than the thickness of the second conductor pattern. As a result, when the electronic component is manufactured while a manufacturing process thereof includes a cutting step, it is possible to ensure an area in which the conductor pattern is disposed. As a result, characteristics of the electronic component can be improved.
(2) In the electronic component according to (1), the conductor patterns of the plurality of conductor layers may have the same thickness.
(3) In the electronic component according to (1) or (2), a flat layer may be disposed between the substrate and the first conductor layer. When the thickness of the first conductor layer (the thickness of the first conductor pattern) increases, a stress of the insulating layer covering the first conductor layer increases, and a crack may occur. In this regard, in the electronic component, the flat layer is disposed between the substrate and the first conductor layer. As a result, in the electronic component, rigidity against a stress can be ensured. Therefore, in the electronic component, the thickness of the first conductor layer can be increased. As a result, in the electronic component, characteristics can be improved.
(4) In the electronic component according to any one of (1) to (3), the insulating layer may contain a resin of bisphenol F. With this configuration, it is possible to suppress peeling of the insulating layer from the substrate.
(5) In the electronic component according to any one of (1) to (4), the plurality of conductor layers covered with the insulating layers may be four or more layers. With this configuration, characteristics of the electronic component can be improved.
(6) In the electronic component according to any one of (1) to (5), the distance may be 10 μm or less. With this configuration, when the electronic component is manufactured while a manufacturing process thereof includes a cutting step, it is possible to ensure an area in which the conductor pattern is disposed.
(7) In the electronic component according to any one of (1) to (6), the adhesion layer may contain at least one material selected from the group consisting of chromium, titanium, tantalum, titanium nitride, and tantalum nitride.
(8) The electronic component according to any one of (1) to (7) may further include a dielectric film covering the adhesion layer, and the dielectric film may be exposed on the one side surface.
(9) In the electronic component according to (8), the dielectric film may contain at least one material selected from the group consisting of silicon nitride, silicon dioxide, and tantalum pentoxide.
(10) In the electronic component according to (8), the dielectric film may include a first dielectric film covering the adhesion layer and a second dielectric film covering the first dielectric film.
(11) In the electronic component according to (10), an end of the first dielectric film may be disposed at the same position as an end of the adhesion layer.
(12) The electronic component according to any one of (1) to (11) may further include an electrode layer disposed on the adhesion layer and including a capacitor pattern, and the first conductor pattern and the capacitor pattern may constitute a capacitor.
(13) In the electronic component according to (12), the capacitor pattern may be coupled to the second conductor pattern.
(14) In the electronic component according to (3), the flat layer may contain alumina or silicon oxide.
(15) In the electronic component according to any one of (1) to (14), the first conductor pattern and the second conductor pattern may contain copper.
(16) In the electronic component according to any one of (1) to (15), the substrate may be formed of a material selected from the group consisting of silicon single crystal, alumina, sapphire, aluminum nitride, MgO single crystal, SrTiO₃ single crystal, surface silicon oxide, glass, quartz, and ferrite.
(17) the electronic component according to any one of (1) to (16) may further include a terminal electrode disposed on one main surface of the element body.
(18) In the electronic component according to (17), the number of the terminal electrodes may be four.
(19) In the electronic component according to any one of (1) to (18), the element body may have a rectangular parallelepiped shape.
(20) In the electronic component according to any one of (1) to (19), the one side surface may be a cut surface formed by cutting a stacked body.

### DETAILS OF EMBODIMENTS OF PRESENT DISCLOSURE

Specific examples of the embodiment of the present disclosure will be described below with reference to the drawings. The present disclosure is not limited to these examples, but is indicated by the claims, and is intended to include all modifications within the meaning and scope equivalent to the claims. In the description of the drawings, the same elements are denoted by the same reference numerals, and redundant description thereof will be omitted.

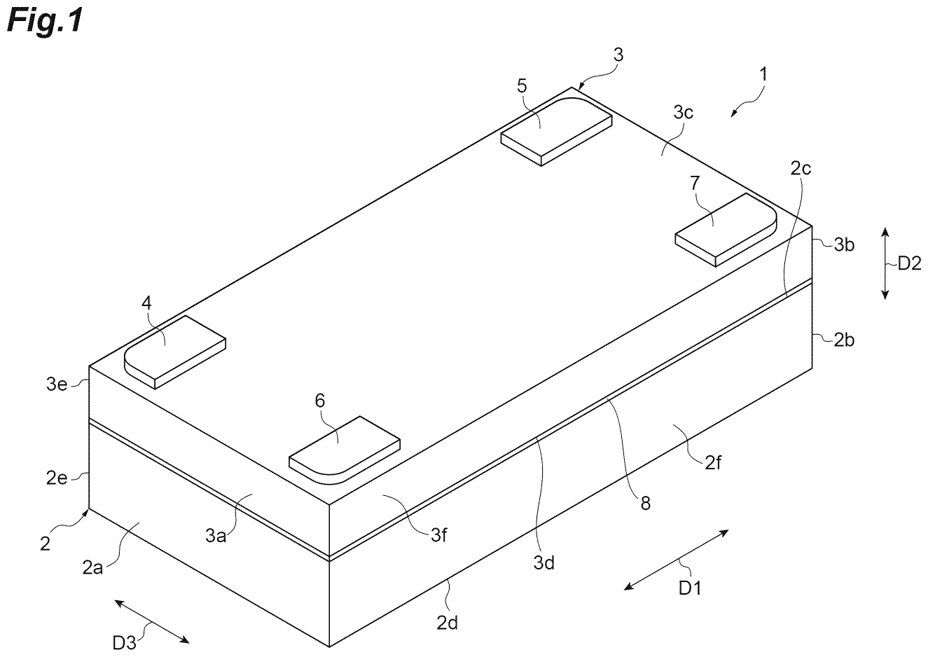

FIG. 1 is a perspective view of an electronic component according to an embodiment. As illustrated in FIG. 1, an electronic component 1 includes: a substrate 2; an element body 3; and a first terminal electrode 4, a second terminal electrode 5, a third terminal electrode 6, and a fourth terminal electrode 7 which are disposed on the element body 3. The electronic component 1 is, for example, a band pass filter.

The substrate 2 has a rectangular parallelepiped shape. The rectangular parallelepiped shape includes a rectangular parallelepiped shape in which corner portions and ridge line portions are chamfered, and a rectangular parallelepiped shape in which corner portions and ridge line portions are rounded. The substrate 2 has, as outer surfaces thereof, a pair of end surfaces 2a and 2b facing each other, a pair of main surfaces 2c and 2d facing each other, and a pair of side surfaces 2e and 2f facing each other.

A facing direction in which the pair of end surfaces 2a and 2b face each other is a first direction D1. A facing direction in which the pair of main surfaces 2c and 2d face each other is a second direction D2. A facing direction in which the pair of side surfaces 2e and 2f face each other is a third direction D3. In the present embodiment, the first direction D1 is a longitudinal direction of the substrate 2. The second direction D2 is a height direction of the substrate 2, and is orthogonal to the first direction D1. The third direction D3 is a width direction of the substrate 2, and is orthogonal to the first direction D1 and the second direction D2.

The pair of end surfaces 2a and 2b extend in the second direction D2 to connect the pair of main surfaces 2c and 2d. The pair of end surfaces 2a and 2b also extend in the third direction D3. The pair of side surfaces 2e and 2f extend in the second direction D2 to connect the pair of main surfaces 2c and 2d. The pair of side surfaces 2e and 2f also extend in the first direction D1.

The substrate 2 is formed of a material that is chemically and thermally stable, generates a less stress, and can maintain surface smoothness. The material is not particularly limited, but silicon single crystal, alumina, sapphire, aluminum nitride, MgO single crystal, SrTiO₃ single crystal, surface silicon oxide, glass, quartz, ferrite, and the like can be used.

The element body 3 has a rectangular parallelepiped shape. The element body 3 has, as outer surfaces thereof, a pair of end surfaces (side surfaces) 3a and 3b facing each other, a pair of main surfaces 3c and 3d facing each other, and a pair of side surfaces 3e and 3f facing each other. The pair of end surfaces 3a and 3b face each other in the first direction D1. The pair of main surfaces 3c and 3d face each other in the second direction D2. The pair of side surfaces 3e and 3f face each other in the third direction D3. In the electronic component 1, the main surface 3c constitutes a mounting surface facing an electronic device or the like.

The pair of end surfaces 3a and 3b extend in the second direction D2 to connect the pair of main surfaces 3c and 3d. The pair of end surfaces 3a and 3b also extend in the third direction D3. The pair of side surfaces 3e and 3f extend in the second direction D2 to connect the pair of main surfaces 3c and 3d. The pair of side surfaces 3e and 3f also extend in the first direction D1. The dimension of the element body 3 in the first direction D1 is equal to the dimension of the substrate 2 in the first direction D1. The dimension of the element body 3 in the third direction D3 is equal to the dimension of the substrate 2 in the third direction D3.

Note that, in the present embodiment, “equal” may mean not only “equal” but also a value including a minute difference, a manufacturing error, or the like in a preset range. For example, when a plurality of values are included within a range of ±5% of an average value of the plurality of values, the plurality of values are defined to be equal.

The substrate 2 and the element body 3 are integrally disposed. The substrate 2 and the element body 3 are disposed such that the main surface 2c and the main surface 3d face each other. A flat layer 8 is disposed between the substrate 2 and the element body 3. The flat layer 8 is disposed between the main surface 2c of the substrate 2 and the main surface 3d of the element body 3. As the flat layer 8, alumina, silicon oxide, or the like can be used.

The first terminal electrode 4, the second terminal electrode 5, the third terminal electrode 6, and the fourth terminal electrode 7 are disposed on the main surface 3c of the element body 3. The first terminal electrode 4, the second terminal electrode 5, the third terminal electrode 6, and the fourth terminal electrode 7 each have a substantially rectangular shape in plan view. The rectangular shape includes a shape in which corner portions and ridge portions are chamfered and a shape in which corner portions and ridge portions are rounded. In the present embodiment, the first terminal electrode 4, the second terminal electrode 5, the third terminal electrode 6, and the fourth terminal electrode 7 each have a shape in which one corner portion is rounded (curved).

The first terminal electrode 4 is disposed at a position close to the end surface 3a and close to the side surface 3e. The second terminal electrode 5 is disposed at a position close to the end surface 3b and close to the side surface 3e. The third terminal electrode 6 is disposed at a position close to the end surface 3a and close to the side surface 3f. The fourth terminal electrode 7 is disposed at a position close to the end surface 3b and close to the side surface 3f.

The first terminal electrode 4 and the second terminal electrode 5 are disposed at an interval in the first direction D1. The third terminal electrode 6 and the fourth terminal electrode 7 are disposed at an interval in the first direction D1. The first terminal electrode 4 and the third terminal electrode 6 are disposed at an interval in the third direction D3. The second terminal electrode 5 and the fourth terminal electrode 7 are disposed at an interval in the third direction D3. Intervals between the terminal electrodes may be appropriately selected according to specifications required for the electronic component 1 and the like.

The first terminal electrode 4, the second terminal electrode 5, the third terminal electrode 6, and the fourth terminal electrode 7 can be each formed of an appropriate conductor (for example, gold, nickel, copper, or silver).

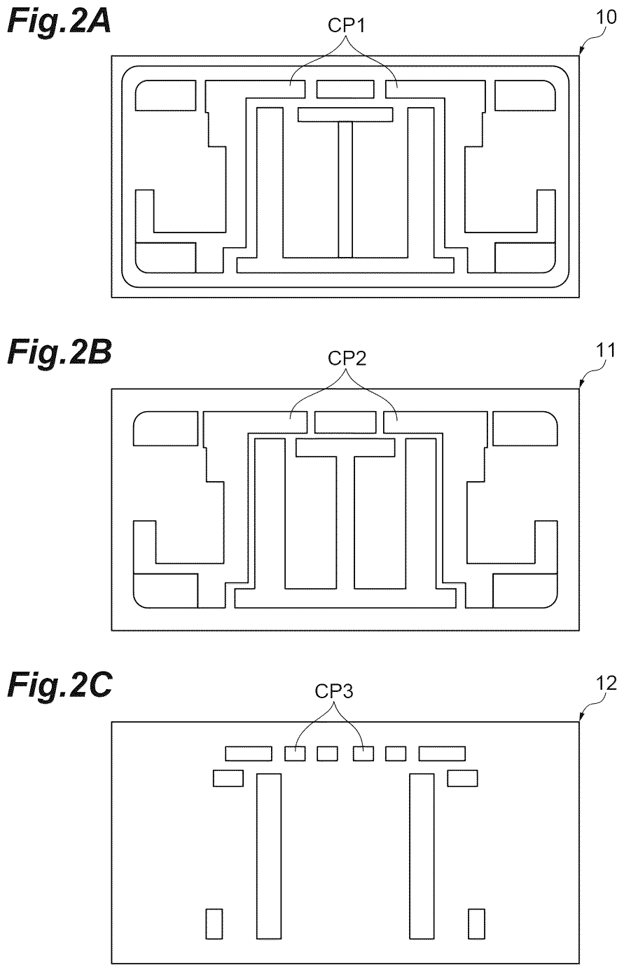

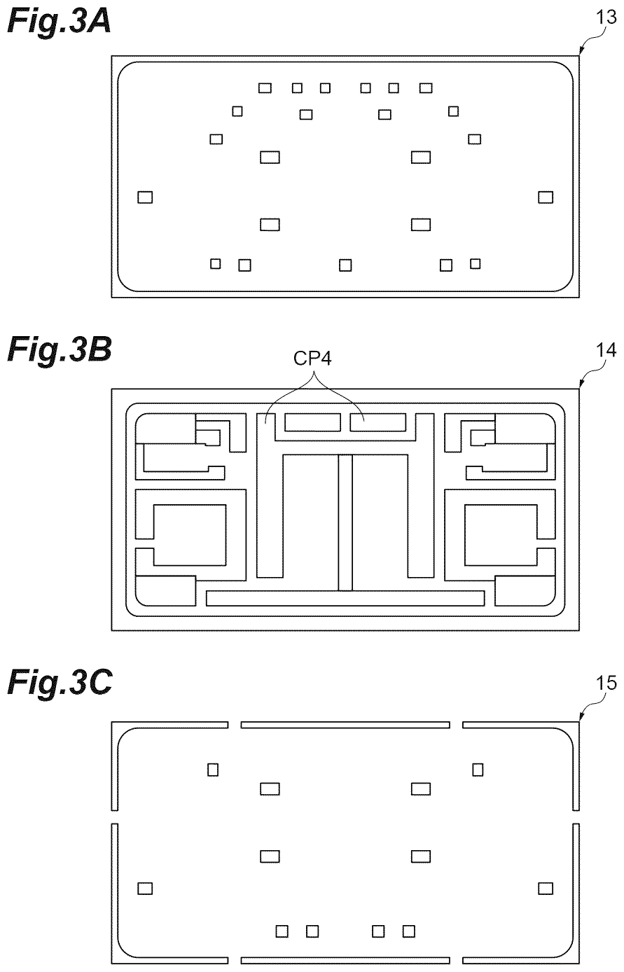

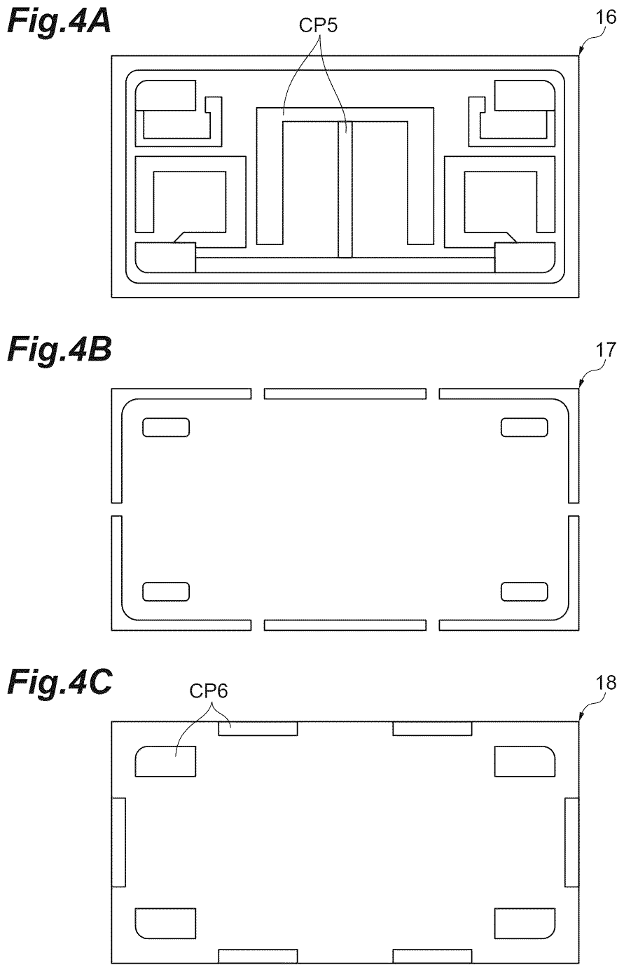

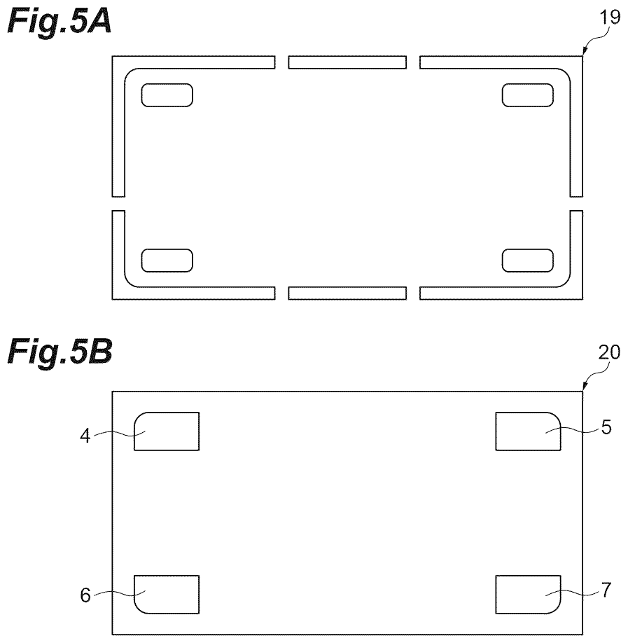

FIGS. 2A, 2B, and 2C are views illustrating layers constituting the element body 3. FIGS. 3A, 3B, and 3C are views illustrating layers constituting the element body 3. FIGS. 4A, 4B, and 4C are views illustrating layers constituting the element body 3. FIGS. 5A and 5B are views illustrating layers constituting the element body 3.

As illustrated in FIGS. 2A, 2B, 2C, 3A, 3B, 3C, 4A, 4B, 4C, 5A, and 5B, the element body 3 includes a first conductor layer 10, an intermediate layer (adhesion layer) 11, an electrode layer 12, a first insulating layer 13, a second conductor layer 14, a second insulating layer 15, a third conductor layer 16, a third insulating layer 17, a fourth conductor layer 18, a fourth insulating layer 19, and a terminal layer 20. The first conductor layer 10, the intermediate layer 11, the electrode layer 12, the first insulating layer 13, the second conductor layer 14, the second insulating layer 15, the third conductor layer 16, the third insulating layer 17, the fourth conductor layer 18, the fourth insulating layer 19, and the terminal layer 20 are disposed in mutually different layers in the second direction D2. In the actual element body 3, the first insulating layer 13, the second insulating layer 15, the third insulating layer 17, and the fourth insulating layer 19 are integrated to such an extent that boundaries between the layers cannot be visually recognized.

The first conductor layer 10 is disposed on the substrate 2. The first conductor layer 10 includes a plurality of first conductor patterns CP1. The first conductor pattern CP1 can be formed of an appropriate conductor (for example, copper).

The intermediate layer 11 is disposed on the first conductor layer 10. The intermediate layer 11 covers the first conductor layer 10. The intermediate layer 11 includes a plurality of patterns CP2. The plurality of patterns CP2 cover the plurality of first conductor patterns CP1 of the first conductor layer 10, respectively. The pattern CP2 can be formed of chromium, titanium, tantalum, titanium nitride, tantalum nitride, or the like.

The electrode layer 12 is disposed on the intermediate layer 11. The electrode layer 12 includes a plurality of capacitor patterns CP3. The capacitor pattern CP3 can be formed of an appropriate conductor (for example, copper). The capacitor pattern CP3 is coupled to a second conductor pattern CP4 (described later) of the second conductor layer 14, and constitutes a capacitor together with the first conductor pattern CP1 of the first conductor layer 10.

The first insulating layer 13 covers the first conductor layer 10. In the present embodiment, the first insulating layer 13 is made of bisphenol F. That is, the element body 3 contains a resin of bisphenol F. Bisphenol F is a soft material having a lower viscosity than conventional bisphenol A, and therefore has a low stress and can suppress peeling of the insulating layer from the substrate. The first insulating layer 13 constitutes the main surface 3d of the element body 3.

The second conductor layer 14 includes the plurality of second conductor patterns CP4. The second conductor pattern CP4 can be formed of an appropriate conductor (for example, copper).

The second insulating layer 15 covers the second conductor layer 14. In the present embodiment, the second insulating layer 15 is made of bisphenol F.

The third conductor layer 16 includes a plurality of third conductor patterns CP5. The third conductor pattern CP5 can be formed of an appropriate conductor (for example, copper).

The third insulating layer 17 covers the third conductor layer 16. The third insulating layer 17 is made of bisphenol F.

The fourth conductor layer 18 includes a plurality of fourth conductor patterns CP6. The fourth conductor pattern CP6 can be formed of an appropriate conductor (for example, copper).

The fourth insulating layer 19 covers the fourth conductor layer 18. The fourth insulating layer 19 is made of bisphenol F. The fourth insulating layer 19 constitutes the main surface 3c of the element body 3.

The terminal layer 20 includes the first terminal electrode 4, the second terminal electrode 5, the third terminal electrode 6, and the fourth terminal electrode 7.

In the electronic component 1, the first conductor pattern CP1 of the first conductor layer 10, the capacitor pattern CP3 of the electrode layer 12, the second conductor pattern CP4 of the second conductor layer 14, the third conductor pattern CP5 of the third conductor layer 16, and the fourth conductor pattern CP6 of the fourth conductor layer 18 constitute an inductor and a capacitor.

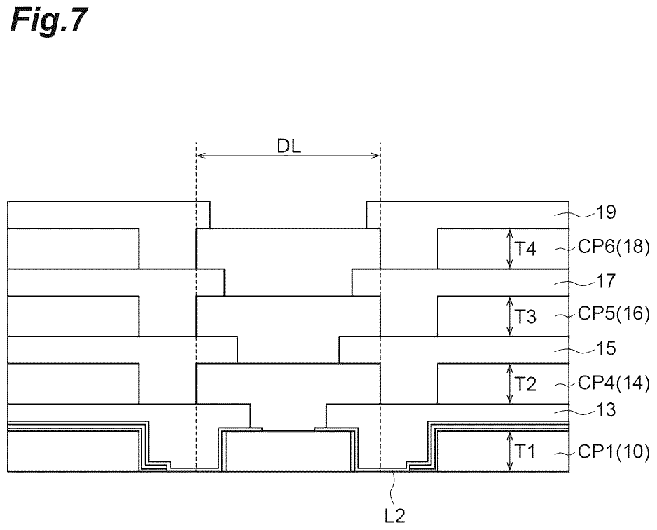

The first conductor pattern CP1 of the first conductor layer 10, the second conductor pattern CP4 of the second conductor layer 14, the third conductor pattern CP5 of the third conductor layer 16, and the fourth conductor pattern CP6 of the fourth conductor layer 18 have thicknesses T1, T2, T3, and T4 (see FIG. 7) which are equal to each other, respectively. That is, the lengths of the first conductor pattern CP1 of the first conductor layer 10, the second conductor pattern CP4 of the second conductor layer 14, the third conductor pattern CP5 of the third conductor layer 16, and the fourth conductor pattern CP6 of the fourth conductor layer 18 in the second direction D2 are equal to each other. The thicknesses T1, T2, T3, and T4 may be, for example, 20 μm.

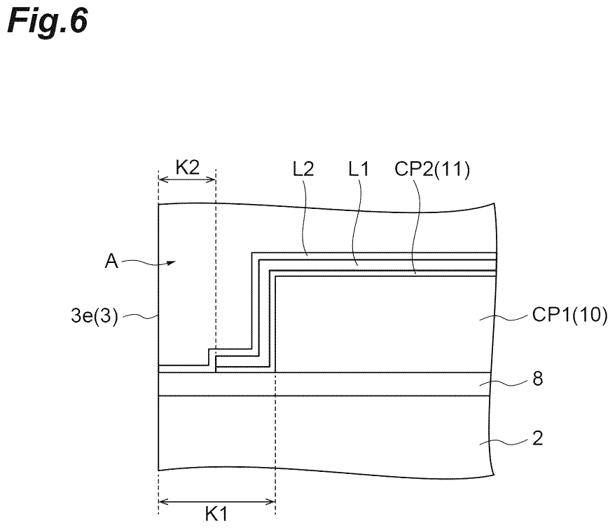

FIG. 6 is an enlarged cross-sectional view illustrating a part of the electronic component 1. In FIG. 6, hatching is not illustrated. As illustrated in FIG. 6, in the electronic component 1, the first conductor pattern CP1 and the side surface 3e of the element body 3 are separated from each other by a distance K1. The distance K1 may be the shortest distance between a side surface of the first conductor pattern CP1 and the side surface 3e of the element body 3. The distance K1 may be, for example, 20 μm or less.

The pattern CP2 of the intermediate layer 11 is covered with a first layer L1 and a second layer L2. The first layer L1 covers the pattern CP2. The first layer L1 may be, for example, silicon nitride, silicon dioxide, or tantalum pentoxide. The first layer L1 has a function of a dielectric film of a capacitor. An end of the first layer L1 is located at the same position as an end of the pattern CP2 of the intermediate layer 11. In the electronic component 1, there is a region A in which a distance K2 between the end (end surface) of the first layer L1 and the side surface 3e of the element body 3, that is, the distance K2 from the side surface 3e (one side surface) to the pattern CP2 of the intermediate layer 11 is equal to or less than the thickness T2 of the second conductor pattern CP4. The distance K2 may be the shortest distance between the side surface 3e of the element body 3 and the pattern CP2 of the intermediate layer 11. The distance K2 may be, for example, 10 μm.

The second layer L2 covers the first layer L1. The second layer L2 may be, for example, silicon nitride, silicon dioxide, or tantalum pentoxide. The first layer L1 and the second layer L2 may be formed of the same material or different materials. The second layer L2 has a function of a dielectric film of a capacitor. The second layer L2 is exposed on the side surface 3e of the element body 3. The first insulating layer 13 is disposed on the second layer L2. That is, the second layer L2 is covered with the first insulating layer 13.

FIG. 7 is a cross-sectional view of a stacked body before the electronic component 1 is divided into individual pieces. In FIG. 7, hatching is not illustrated. As illustrated in FIG. 7, a dicing line DL into which a dicing blade (cutting blade) advances is set in a stacked body 100. The length of the dicing line DL may be, for example, 70 μm. When the stacked body 100 is divided into individual pieces, the dicing blade is moved along the dicing line DL. The dicing blade cuts the first insulating layer 13, the second insulating layer 15, the third insulating layer 17, and the fourth insulating layer 19, and also cuts the second layer L2. As a result, the stacked body 100 is cut and divided into individual pieces as the electronic components 1.

As described above, in the electronic component 1 according to the present embodiment, the first conductor pattern CP1 is covered with the intermediate layer 11. This makes it possible to suppress peeling of the first conductor pattern CP1 when cutting is performed in a manufacturing process. Therefore, the electronic component 1 has a region A in which the distance K2 from the side surface 3e of the element body 3 to the pattern CP2 of the intermediate layer 11 is equal to or less than the thickness T2 of the second conductor pattern CP4. As a result, when the electronic component 1 is manufactured while a manufacturing process thereof includes a cutting step, a design area can be ensured. As a result, characteristics of the electronic component 1 can be improved.

In the electronic component 1 according to the present embodiment, the flat layer 8 is disposed between the substrate 2 and the first conductor layer 10. When the thickness of the first conductor layer 10 (the thickness of the first conductor pattern CP1) increases, a stress of the insulating layer covering the first conductor layer 10 increases, and a crack may occur. In this regard, in the electronic component 1, the flat layer 8 is disposed between the substrate 2 and the first conductor layer 10. As a result, in the electronic component 1, rigidity against a stress can be ensured. Therefore, in the electronic component 1, the thickness of the first conductor layer 10 can be increased. As a result, in the electronic component 1, characteristics can be improved.

In the electronic component 1 according to the present embodiment, the first insulating layer 13, the second insulating layer 15, the third insulating layer 17, and the fourth insulating layer 19 contain a resin of bisphenol F. With this configuration, it is possible to suppress peeling of the first insulating layer 13 from the substrate 2.

In the electronic component 1 according to the present embodiment, the distance K2 may be 10 μm or less. With this configuration, when the electronic component 1 is manufactured while a manufacturing process thereof includes a cutting step, it is possible to ensure an area in which the first conductor pattern CP1 is disposed.

Although the embodiment of the present disclosure has been described above, the present disclosure is not necessarily limited to the above-described embodiment, and various modifications can be made without departing from the gist thereof.

In the above embodiment, a mode in which the element body 3 includes the first conductor layer 10, the second conductor layer 14, the third conductor layer 16, and the fourth conductor layer 18 has been described as an example. However, the element body 3 only needs to include at least two conductor layers.

In the above embodiment, a mode in which there is the region A in which the distance K1 between the first conductor pattern CP1 and the side surface (one side surface) 3e of the element body 3 is equal to or less than the thickness T2 of the second conductor pattern CP4 has been described as an example. However, there may be a region A in which the distance K1 between the first conductor pattern CP1 and the side surface (one side surface) 3f of the element body 3 is equal to or less than the thickness T2 of the second conductor pattern CP4, there may be a region A in which the distance K1 between the first conductor pattern CP1 and the end surface 3a of the element body 3 is equal to or less than the thickness T2 of the second conductor pattern CP4, or there may be a region A in which the distance K1 between the first conductor pattern CP1 and the end surface 3b of the element body 3 is equal to or less than the thickness T2 of the second conductor pattern CP4.

1. An electronic component comprising:
a substrate; and
an element body disposed on the substrate and including a pair of main surfaces facing each other and four side surfaces connecting the pair of main surfaces, wherein
the element body includes a plurality of conductor layers and insulating layers,
the plurality of conductor layers include a first conductor layer disposed on the substrate and a second conductor layer disposed on the first conductor layer,
the first conductor layer includes a first conductor pattern,
the second conductor layer includes a second conductor pattern,
the first conductor pattern is covered with an adhesion layer, and
there is a region in which a distance from one of the side surfaces to the adhesion layer is equal to or less than a thickness of the second conductor pattern.

2. The electronic component according to claim 1, wherein the conductor patterns of the plurality of conductor layers have the same thickness.

3. The electronic component according to claim 1, wherein a flat layer is disposed between the substrate and the first conductor layer.

4. The electronic component according to claim 1, wherein the insulating layer contains a resin of bisphenol F.

5. The electronic component according to claim 1, wherein the plurality of conductor layers covered with the insulating layers are four or more layers.

6. The electronic component according to claim 1, wherein the distance is 10 μm or less.

7. The electronic component according to claim 1, wherein the adhesion layer contains at least one material selected from the group consisting of chromium, titanium, tantalum, titanium nitride, and tantalum nitride.

8. The electronic component according to claim 1, further comprising a dielectric film covering the adhesion layer, wherein
the dielectric film is exposed on the one side surface.

9. The electronic component according to claim 8, wherein the dielectric film contains at least one material selected from the group consisting of silicon nitride, silicon dioxide, and tantalum pentoxide.

10. The electronic component according to claim 8, wherein the dielectric film includes a first dielectric film covering the adhesion layer and a second dielectric film covering the first dielectric film.

11. The electronic component according to claim 10, wherein an end of the first dielectric film is disposed at the same position as an end of the adhesion layer.

12. The electronic component according to claim 1, further comprising an electrode layer disposed on the adhesion layer and including a capacitor pattern, wherein
the first conductor pattern and the capacitor pattern constitute a capacitor.

13. The electronic component according to claim 12, wherein the capacitor pattern is coupled to the second conductor pattern.

14. The electronic component according to claim 3, wherein the flat layer contains alumina or silicon oxide.

15. The electronic component according to claim 1, wherein the first conductor pattern and the second conductor pattern contain copper.

16. The electronic component according to claim 1, wherein the substrate is formed of a material selected from the group consisting of silicon single crystal, alumina, sapphire, aluminum nitride, MgO single crystal, SrTiO₃ single crystal, surface silicon oxide, glass, quartz, and ferrite.

17. The electronic component according to claim 1, further comprising a terminal electrode disposed on one of the main surfaces of the element body.

18. The electronic component according to claim 17, wherein the number of the terminal electrodes is four.

19. The electronic component according to claim 1, wherein the element body has a rectangular parallelepiped shape.

20. The electronic component according to claim 1, wherein the one side surface is a cut surface formed by cutting a stacked body.
